(19) United States
(12) Patent Application Publication
(10) Pub. No.: US 2006/0120422 A1
(43) Pub. Date: Jun. 8, 2006

(54) Laser device and controlling method thereof

(75) Inventors: Masamichi Yamanishi, Hamamatsu-shi (JP); Naota Akikusa, Hamamatsu-shi (JP); Tadataka Edamura, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K.

(21) Appl. No.: 11/272,025

(22) Filed: Nov. 14, 2005

(30) Foreign Application Priority Data
Nov. 15, 2004 (JP) P2004-331134

(51) Int. Cl. H01S 5/00

(52) U.S. Cl. 372/43.01

(57) ABSTRACT

A laser device includes a laminated body obtained by laminating a plurality of semiconductor layers on a semiconductor substrate. One semiconductor layer of the plurality of semiconductor layers is an active layer in which a light-emission region and an injecting region are alternately laminated. The laser device is provided with a cascade laser element for outputting light L generated in the active layer from a first end face included in the laminated body, a part for supplying a voltage to the laser element and driving the laser element, a part for supplying an elastic wave traveling in the direction orthogonal to the first end face of the laminated body to the active layer, and a part for supplying a turn-on voltage in which the gain of the laser element becomes the approximate maximum value to the laser element by the element driving part, and supplying the elastic wave to the active layer by the elastic wave supplying part.

### BACKGROUND OF THE INVENTION

1. Field of the Invention

The present invention relates to a laser device using a cascade laser element for outputting light having a wavelength of an infrared region, and a controlling method thereof.

2. Related Background of the Invention

Attention has been recently focused on a quantum cascade laser element as a semiconductor laser element for outputting the light having a wavelength of an infrared region (for example, refer to Japanese Published Unexamined Patent Application No. H08-279647). An active layer of the quantum cascade laser element has a cascade structure obtained by alternately laminating a light-emission region generating light by an intersubband transition in a quantum well structure and an injecting region for injecting electrons into the light-emission region, and the light can be outputted in a cascade from each of the light-emission regions provided in multiple stages.

Since the interaction between the light having the wavelength of the infrared region, outputted from the quantum cascade laser element and an organic substance is large, for example, the wavelength area of the light is effective for analysis of the organic substance. Therefore, the use of the quantum cascade laser element as a light source for spectroscopic analysis has been expected. Also, since a light communication field requires the light having the wavelength of the infrared region, the use of the quantum cascade laser element as a light source used for a light communication system has been also expected.

As the light source used in the spectroscopic analysis field and the light communication field, a wavelength-variable light source capable of outputting light of a single wavelength has been required. Although a distribution feedback type building in a diffraction grating near the active layer for turning the light outputted by the semiconductor laser element as a single mode and outputting light having a wavelength satisfying the Bragg condition has been known, the wavelength cannot be changed when the diffraction grating is built in the semiconductor laser element.

It is considered that refractive-index distribution is formed in the active layer by supplying an elastic wave to the active layer, and the distribution feedback is realized by the refractive-index distribution. However, since the propagation loss of the elastic wave is proportional to the square of frequencies, it may be difficult to generate the light efficiently according to the constitution of the laser device.

It is an aspect of the present invention to provide a laser device capable of efficiently outputting the light of the single wavelength in the infrared region and changing the wavelength, and a method for controlling the laser device.

### SUMMARY OF THE INVENTION

So as to solve the above problem, the present inventors have focused attention on the nonlinearity of gain of the quantum cascade laser element actually confirmed by the measurement of the inventors. The active layer of the quantum cascade laser element has a cascade structure obtained by alternately laminating the light-emission region for generating the light and the injecting region for injecting the electrons into the light-emission region. The quantum cascade laser element applies an internal electrical field to the active layer by applying a bias voltage and matches the ground level of the injecting region with the excitation level of the light-emission region to inject the electrons into the light-emission region from the injecting region and generate the light. In this case, when the internal electrical field is further increased, inconsistency occurs between the ground level of the injecting region and the excitation level of the light-emission region, and as a result, the gain is decreased. That is, in the quantum cascade laser element, the gain has the nonlinearity, and a turn-on electrical field where the gain becomes the maximum value and a turn-on voltage for producing the turn-on electrical field in the active layer exist.

The present inventors have found that the gain distribution having a period shorter than that of refractive-index distribution of the elastic wave can be formed in the active layer by using the nonlinearity of the gain of the quantum cascade laser element and the elastic wave, and the present invention was accomplished.

That is, the laser device according to an aspect of the present invention, comprising: (1) a cascade laser element including a laminated body having a plurality of semiconductor layers laminated on a semiconductor substrate and outputting light generated in an active layer from a first end face of the first and second end faces contained in the laminated body and opposing each other, one semiconductor layer of the plurality of semiconductor layers being the active layer in which a light-emission region generating light by an intersubband transition in a quantum well structure and an injecting region injecting electrons into the light-emission region are alternately laminated along the laminating direction of the plurality of semiconductor layers and which has piezoelectricity; (2) element driving means for supplying a voltage to the cascade laser element to drive the cascade laser element; (3) elastic wave supplying means for supplying an elastic wave traveling in the direction approximately orthogonal to the first end face to the active layer; and (4) controlling means for supplying a turn-on voltage in which the gain of the cascade laser element becomes the approximate maximum value to the cascade laser element by the element driving means, and for supplying the elastic wave to the active layer by the elastic wave supplying means.

In this constitution, the controlling means sets the gain of the cascade laser element to the approximate maximum value by supplying the turn-on voltage to the cascade laser element by the element driving means, and makes the elastic wave supplying means supply the elastic wave into the active layer. In this case, strain distribution is formed along the traveling direction of the elastic wave in the active layer by the supply of the elastic wave. The strain distribution makes refractive-index distribution by a photoelastic effect. Since the active layer has piezoelectricity, the strain makes electrical field distribution simultaneously, and the electrical field in the active layer is periodically modulated.

A gain is decreased when the electrical field is increased or decreased in the state where the gain becomes the approximate maximum value in the cascade laser element. As a result, gain distribution having a period narrower than the period of the refractive-index distribution according to the strain distribution is formed in the active layer. Since this gain distribution functions as a diffraction grating, a distribution feedback is realized by the gain distribution.

Since the period of the gain distribution is smaller than the period of the refractive-index distribution formed by the elastic wave, the frequency of the elastic wave required for outputting light of a desired wavelength can be reduced. As a result, since the propagation loss of the elastic wave is reduced, the light of a single wavelength can be efficiently and reliably outputted. The wavelength can be easily changed by adjusting the frequency of the elastic wave.

A method for controlling a laser device according to another aspect of the present invention, comprising: (1) a turn-on voltage setting step for setting a turn-on voltage in which a gain of a cascade laser element for outputting light generated in an active layer from a first end face of the first and second end faces contained in the laminated body and opposing each other becomes the approximate maximum value, in a laser device including a laminated body having a plurality of semiconductor layers laminated on a semiconductor substrate, one semiconductor layer of the plurality of semiconductor layers being the active layer in which a light-emission region generating light by an intersubband transition in a quantum well structure and an injecting region injecting electrons into the light-emission region are alternately laminated along the laminating direction of the plurality of semiconductor layers; (2) an element driving step for supplying the set turn-on voltage to the cascade laser element to drive the cascade laser element; and (3) an elastic wave supplying step for supplying an elastic wave traveling in the direction approximately orthogonal to the first end face to the active layer of the cascade laser element.

Since the cascade laser element is driven by supplying the turn-on voltage set in the turn-on voltage setting step in this constitution, the gain of the cascade laser element driven in the element driving step becomes the approximate maximum value. When the elastic wave is supplied into the active layer in the elastic wave supplying step at this time, the strain distribution is formed along the traveling direction of the elastic wave in the active layer, and the active layer has piezoelectricity. Thereby, the electrical field in the active layer is modulated according to the strain.

The gain is decreased when the electrical field is increased or decreased in the state where the gain becomes the approximate maximum value in the cascade laser element. As a result, the gain distribution having a period narrower than the period of the refractive-index distribution according to the strain is formed in the active layer. Since this gain distribution functions as a diffraction grating, the distribution feedback is realized by the gain distribution.

Since the period of the gain distribution is smaller than the period of the refractive-index distribution formed by the elastic wave, the frequency of the elastic wave required for outputting light of a desired wavelength can be reduced. As a result, since the propagation loss of the elastic wave is reduced, the light of a single wavelength can be efficiently and reliably outputted. The wavelength can be easily changed by adjusting the frequency of the elastic wave.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a block diagram showing the constitution of a spectroscopic analysis system using one embodiment of a laser device according to the present invention.

FIG. 2 is a schematic view showing the constitution of one embodiment of the laser device according to the present invention.

FIG. 3 shows a model of a band structure of an active layer.

FIG. 4 shows the relationship between an internal electrical field and a gain.

FIG. 5 shows an electrical field distribution due to an elastic wave in the active layer and a gain distribution generated by the electrical field distribution.

FIG. 6 is a flow chart showing a method for controlling the laser device.

FIG. 7 is a schematic view showing the constitution of another embodiment of the laser device according to the present invention.

FIG. 8 is a schematic view showing the constitution of another embodiment of the laser device according to the present invention.

FIG. 9 is a schematic view showing the constitution of another embodiment of the laser device according to the present invention.

### DESCRIPTION OF THE PREFERRED EMBODIMENTS

Hereinafter, the preferred embodiments of the laser device and method for controlling the laser device according to the present invention will be described below with reference to the drawings.

### First Embodiment

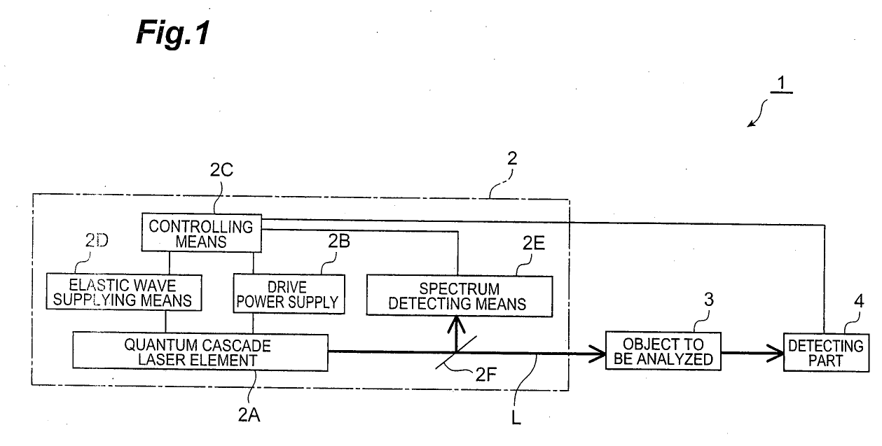

FIG. 1 is a block diagram showing the constitution of a spectroscopic analysis system using a laser device according to the first embodiment.

A spectroscopic analysis system 1 is provided with a laser device 2 for outputting light L having the wavelength of a mid-infrared to far-infrared region as a light source, an object 3 to be analyzed such as an organic substance, and a detecting part 4. The detecting part 4 detects the transmitted light transmitting the object 3 to be analyzed out of the light L outputted from the laser device 2. The detecting part 4 is, for example, an MCT detector.

The laser device 2 has a GaAs/AlGaAs system quantum cascade laser element (hereinafter, referred to merely as “laser element”) 2A for outputting the light L, and a drive power supply 2B for driving the laser element 2A as an element driving means. The drive power supply 2B constitutes a part of the laser device 2, and is electrically connected to a controlling means 2C for controlling each constituent element of the laser device 2. The laser element 2A is driven by applying a voltage set by the controlling means 2C to the laser element 2A.

For example, the drive power supply 2B is a pulse power supply when outputting the pulse-like light L from the laser element 2A and the drive power supply 2B is a direct-current power supply when continuously oscillating. The controlling means 2C is a personal computer (PC) provided with a CPU containing, for example, a ROM and a RAM or the like, and has a function for analyzing (performing spectroscopic analysis) the detection result of the detecting part 4.

So as to make the light L outputted from the laser element 2A have a single wavelength, the distribution feedback using the elastic wave is adopted in the laser device 2. The laser device 2 has an elastic wave supplying means 2D for supplying the elastic wave to the laser element 2A. Furthermore, the laser device 2 has a spectrum detecting means 2E for detecting the spectrum state of the light L. The spectrum detecting means 2E is, for example, an infrared spectrophotometer, and detects the light split by a half mirror 2F out of the light L outputted from the laser element 2A.

The spectrum detecting means 2E is electrically connected to the controlling means 2C. The controlling means 2C controls the elastic wave supplying means 2D according to the detection result of the spectrum detecting means 2E, and adjusts the frequency and amplitude of the elastic wave supplied to the laser element 2A to optimize the spectrum of the light L. As a result, since the light L of the single wavelength of which the spectrum state is optimized is outputted from the laser device 2, the laser device 2 is an effective light source in the spectroscopic analysis system 1.

Next, the laser device 2 will be explained in detail.

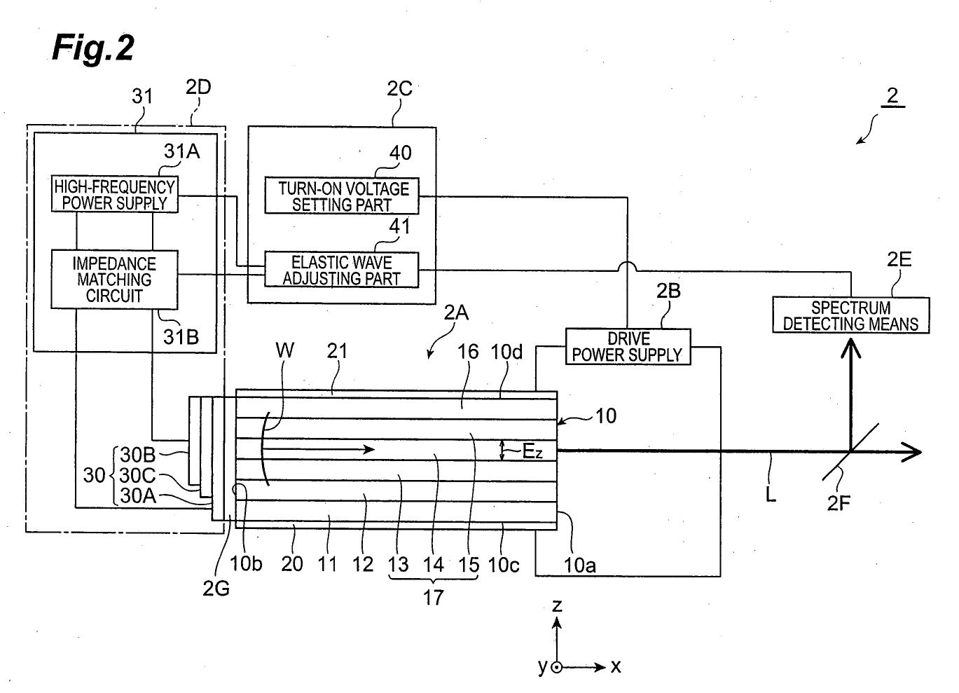

As shown in FIG. 2, the laser element 2A of the laser device 2 has a laminated body 10. The laminated body 10 is constituted by sequentially laminating a clad layer 12 as an n-type semiconductor layer, a waveguide core layer 13, an active layer 14, a waveguide core layer 15 and a clad layer 16 on a semiconductor substrate 11 made of n-type GaAs. The laminated body 10 is produced on the semiconductor substrate 11, for example, by growing the clad layers 12 and 16, the waveguide core layers 13 and 15 and the active layer 14 by using a solid source MBE method. Table 1 shows the typical thickness and carrier concentration of the clad layers 12 and 16, the waveguide core layers 13 and 15 and the active layer 14.

TABLE 1

| | Thickness | Carrier concentration |
|---|---|---|
| | (μm) | (cm⁻³) |
| Clad Layer 16 | 1.0 | 6 × 10¹⁷ |
| Waveguide Core Layer 15 | 1.55 | 4 × 10¹⁶ |
| Active Layer 14 | 1.4 | — |
| Waveguide Core Layer 13 | 1.4 | 4 × 10¹⁶ |
| Clad Layer 12 | 0.6 | 6 × 10¹⁷ |

An antireflection film coat and a high reflection film coat are, respectively, applied on a front side edge face 10a (first end face) and back side edge face (second end face) 10b of the laminated body 10, opposing each other, and thereby a light resonator of the laser element 2A is constituted. The antireflection film coat of the front side edge face 10a may not be formed. In the following explanation, the laminating direction of the clad layers 12 and 16, waveguide core layers 13 and 15 and active layer 14 is set to a z-axial direction, and the direction (a light axial direction of the light resonator) orthogonal to the front side edge face 10a is set to an x-axial direction. The direction orthogonal to the z-axial direction and the x-axial direction is set to a y-axial direction.

Laminated electrodes 20 and 21 made of AuGe/Ni/Au and Ti/Au are, respectively, formed on a lower surface 10c and upper surface 10d of the laminated body 10 by an evaporation method and a sputtering method or the like, and the electrodes 20 and 21 are electrically connected to the drive power supply 2B. Therefore, an internal electrical field E_{z} having a component in the z-axial direction can be applied to the active layer 14 by applying a voltage to electrodes 20 and 21 by the drive power supply 2B.

The active layer 14 is a semiconductor layer for generating light having a wavelength of a mid-infrared to far-infrared region by using an intersubband transition of a quantum well structure. So as to guide the light generated by the active layer 14, the waveguide core layers 13 and 15 being adjacent to the active layer 14 and made of n-type GaAs are arranged, and the clad layers 12 and 16 are arranged so as to be adjacent to the waveguide core layers 13 and 15. In this constitution, the clad layer 12 is in contact with the semiconductor substrate 11, and the clad layer 16 is in contact with the waveguide core layer 15. The clad layers 12 and 16 are made of n-type AlGaAs, and have a refractive-index lower than those of the active layer 14 and waveguide core layers 13 and 15. Thereby, the light generated by the active layer 14 is confined in a waveguide 17 made of the active layer 14 and the waveguide core layers 13 and 15, and is propagated in the x-axial direction.

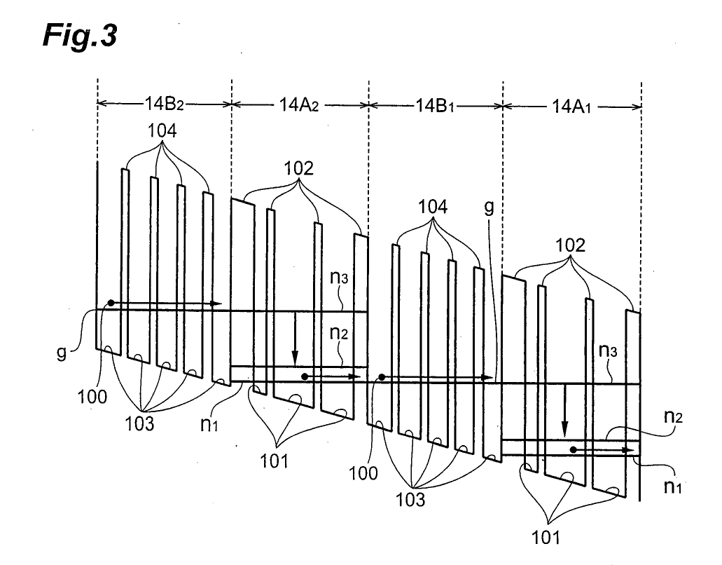

FIG. 3 shows a model of the band structure of the active layer 14. The active layer 14 has a plurality of light-emission regions 14A generating the light by the intersubband transition in the quantum well structure and a plurality of injecting regions 14B for efficiently injecting the electrons into the light-emission region 14A. The active layer 14 is obtained by laminating a fundamental periodic structure consisting of a pair of light-emission regions 14A and injecting regions 14B in 30 stages, and the injecting regions 14B are, respectively, formed between the light-emission regions 14A to which the light-emission regions 14A provided in multiple stages are adjacent, thereby forming a cascade structure. In FIG. 3, the cascade structure is shown for two light-emission regions 14A₁ and 14A₂ and the injecting regions 14B₁ and 14B₂ being adjacent thereto, out of a plurality of light-emission regions 14A and injecting regions 14B constituting the active layer 14.

The light-emission region 14A is composed by alternately laminating a GaAs layer as a quantum well layer 101 and an AlGaAs layer as a quantum barrier layer 102 in the z-axial direction, and the light-emission region 14A has a GaAs/AlGaAs multiquantum well structure. The injecting region 14B is composed by alternately laminating a GaAs layer as a quantum well layer 103 and an AlGaAs layer as a quantum barrier layer 104, and the injecting region 14B has a GaAs/AlGaAs superlattice structure. Table 2 shows the typical thickness and carrier concentration of the GaAs layer and AlGaAs layer of the light-emission region 14A and injecting region 14B.

TABLE 2

| | | Thickness | Carrier concentration |
|---|---|---|---|
| | | (nm) | (cm⁻³) |
| Injecting | GaAs layer | 3.2 | Non Dope |
| Region 14B | AlGaAs layer | 2.0 | Non Dope |
| | GaAs layer | 2.8 | 4 × 10¹⁷ |
| | AlGaAs layer | 2.3 | 4 × 10¹⁷ |
| | GaAs layer | 2.3 | 4 × 10¹⁷ |
| | AlGaAs layer | 2.5 | 4 × 10¹⁷ |
| | GaAs layer | 2.3 | Non Dope |
| | AlGaAs layer | 2.5 | Non Dope |
| | GaAs layer | 2.1 | Non Dope |
| Light-Emission | AlGaAs layer | 5.8 | Non Dope |
| Region 14A | GaAs layer | 1.5 | Non Dope |
| | AlGaAs layer | 2.0 | Non Dope |
| | GaAs layer | 4.9 | Non Dope |
| | AlGaAs layer | 1.7 | Non Dope |
| | GaAs layer | 4.0 | Non Dope |
| | AlGaAs layer | 3.4 | Non Dope |

Herein, a light-emission process in the active layer 14 will be explained. When a bias voltage is applied through the electrodes 20 and 21 from the drive power supply 2B in the active layer 14, the internal electrical field E_{z} having the component in the z-axial direction is produced in the active layer 14. Ground level g formed in the injecting region 14B₂ by the internal electrical field E_{z} and excitation level n3 of the light-emission region 14A₁ are degenerated to form a resonance tunnel state.

In the resonance tunnel state, the electron 100 is alternatively injected into the excitation level n3 of the light-emission region 14A₂, and the electron 100 is transited to the excitation level n2 of the light-emission region 14A₂. As a result, the light of the wavelength equivalent to the energy difference between the excitation level n3 and the excitation level n2 is generated to produce a gain. For example, when the energy difference of the excitation level n3 and the excitation level n2 is 200 meV, the wavelength of the light generated in light-emission region 14A₂ is the wavelength of the mid-infrared region.

Further, the electron 100 transmitted to the excitation level n2 tunnels the injecting region 14B₁. The electron 100 is injected into the excitation level n3 of the light-emission region 14A₁, and the light is similarly generated by the intersubband transition. As described above, since the light-emission region 14A is provided in multiple stages (for example, 30 stages) in the active layer 14, the electron 100 generates the light by the intersubband transition in each light-emission region 14A by moving a plurality of light-emission regions 14A one after another in a cascade manner.

So as to perform laser oscillation of the light of a desired wavelength alternatively out of the light generated in the active layer 14, the laser device 2 has the elastic wave supplying means 2D, as shown in FIG. 2.

The elastic wave supplying means 2D has a piezoelectric element 30 as a means for generating the elastic wave and an exciting power supply part 31 for exciting the piezoelectric element 30. The exciting power supply part 31 has a high-frequency power supply 31A for supplying an AC voltage to the piezoelectric element 30 and an impedance matching circuit 31B for automatically matching impedance.

The piezoelectric element 30 is provided on an insulating film 2G provided on the back side edge face 10b. The insulating film 2G is made of SiO₂ and SiN or the like, and constitutes a part of the laser devices 2. The insulating film 2G is formed by the evaporation method or the sputtering method, and the thickness thereof is, for example, 0.8 μm. The insulating film 2G may be basically formed on the waveguide 17 of the back side edge face 10b.

The piezoelectric element 30 is composed by sandwiching a piezoelectric film 30C made of a piezoelectric material such as ZnO between a pair of metal films 30A and 30B. The piezoelectric film 30C is formed by the evaporation method and the sputtering method or the like on the metal film 30A, and the thickness thereof is, for example, about 1 μm. The metal films 30A and 30B are made of, for example, gold (Au), and the metal films 30A and 30B are, respectively, formed on the insulating film 2G and the piezoelectric film 30C by the evaporation method and the sputtering method or the like. One example of the thickness of the metal film 30A is about 0.3 μm, and one example of the thickness of the metal film 30B is about 0.7 μm. The metal films 30A and 30B are electrically connected to the high-frequency power supply 31A via the impedance matching circuit 31B.

Since the metal film 30A is located at the side of the waveguide 17, for example, the light resonator can also be constituted by the metal film 30A and the front side edge face 10a when the metal film 30A is made of Au. In this case, a high reflection film coat may not be applied to the back side end face 10b.

The piezoelectric element 30 is expanded and contracted in the direction (x-axial direction) orthogonal to the front side edge face 10a and the back side edge face 10b by applying the AC voltage to the metal films 30A and 30B by the exciting power supply part 31. Since the piezoelectric element 30 is located on the waveguide 17 of the back side edge face 10b (at the side of the waveguide 17 in FIG. 2), the piezoelectric element 30 supplies an elastic wave W having the frequency of the AC voltage applied to the metal films 30A and 30B as the frequency ν into the waveguide 17 starting from the back side edge face 10b.

Usually, the phase velocity of the elastic wave depends on the density ρ and elastic constant c of a medium in which the elastic wave is propagated, and is in inverse proportion to the square root of the density ρ. Since the size of the refractive-index corresponds to the size of the density, the waveguide for the light functions as the waveguide for the elastic wave. As a result, the elastic wave. W is propagated in the waveguide 17 consisting of the active layer 14 and the waveguide core layers 13 and 15 as a longitudinal wave toward the front side edge face 10a from the back side edge face 10b. Thereby, the refractive-index distribution is formed along the traveling direction in the waveguide 17.

Since a III-V compound semiconductor constituting the active layer 14 and the waveguide core layers 13 and 15 has piezoelectricity, the electrical field having the component in the z-axial direction in the active layer 14 by the elastic wave W is newly generated, and as a result, the internal electrical field E₂ applied to the active layer 14 is modulated.

The laser device 2 produces the gain distribution along the x-axial direction in the active layer 14 by using the electrical field modulation in the active layer 14 due to the elastic wave W and the nonlinearity of the gain contained in the laser element 2A actually measured and confirmed by the present inventors, and realizes the distribution feedback.

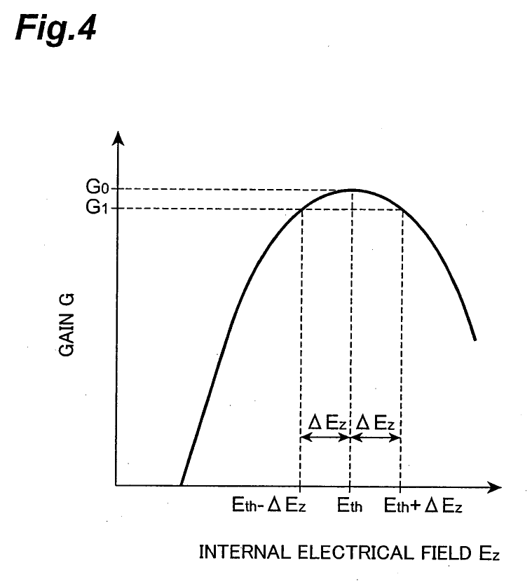

Firstly, the nonlinearity of the gain in the laser element 2A will be explained using FIG. 4. FIG. 4 shows the relationship between the internal electrical field E_{z} and the gain G of the laser element 2A in the active layer 14. In FIG. 4, the horizontal axis shows the internal electrical field E_{z}, and the vertical axis shows the gain G.

As described above, in the active layer 14 of the laser element 2A, the light is generated by setting the excitation level n3 of the light-emission region 14A and the ground level g of the injecting region 14B to the resonance tunnel state by applying the internal electrical field E_{z}. When the gain G exceeds the loss by increasing the injecting current flowing into the active layer 14, the laser oscillation can be attained. When the injecting current is further increased (that is, the internal electrical field E_{z} becomes still larger), inconsistency occurs between the ground level g of the injecting region 14B, and the excitation level n3 of the light-emission region 14A. As a result, a tunnel resonance condition is suppressed, and the gain G is conversely decreased.

Therefore, as shown in FIG. 4, the laser element 2A has the nonlinearity on the gain G, and a turn-on electrical field Eₜₕ as a threshold electrical field in the active layer 14 in which the gain G becomes the maximum value G₀ exists.

Next, a method for forming the gain distribution using the nonlinearity of the gain G of the laser element 2A will be explained. As shown in FIG. 4, when the inner electrical fields E_{z} is increased and decreased at about the same degree (for example, ΔE_{z}) from the turn-on electrical field Eₜₕ, the gain. G is similarly decreased from the maximum value G₀, and is set to G₁. Therefore, the gain distribution can be formed in the active layer 14 by periodically modulating the internal electrical field E_{z} from the turn-on electrical field Eₜₕ. In the laser device 2, the internal electrical field E_{z} is periodically modulated by supplying the elastic wave W to the laser element 2A operated in the turn-on electrical field Eₜₕ to form the gain distribution.

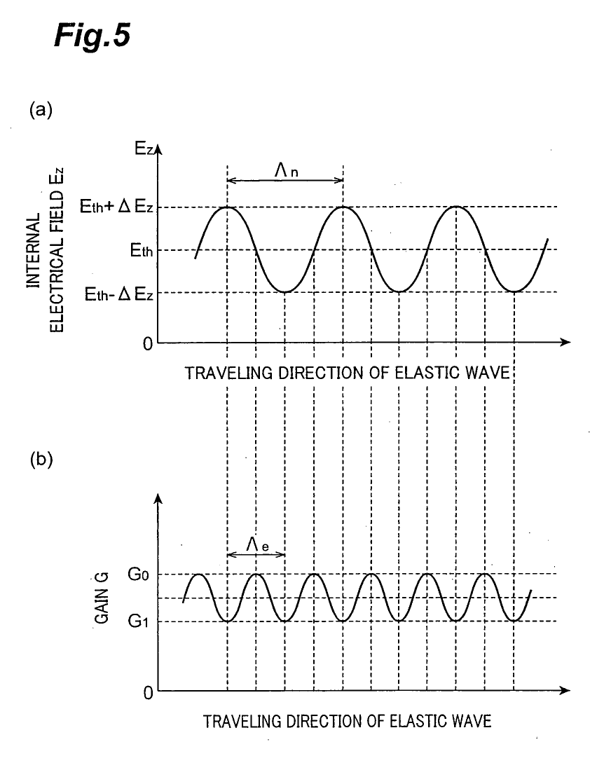

The above content will be more concretely explained using FIG. 5. FIG. 5(a) shows the electrical field distribution in the active layer 14. The horizontal axis shows the traveling direction of the elastic wave W, and the vertical axis shows the internal electrical field E_{z}. FIG. 5(b) shows the gain distribution in the active layer 14. The horizontal axis shows the traveling direction of the elastic wave W, and the vertical axis shows the gain G.

The strain distribution is formed in the active layer 14 by supplying the elastic wave W to the laser element 2A operated in the turn-on electrical field Eₜₕ. The strain distribution forms refractive-index distribution according to the photoelastic effect, and as shown in FIG. 5(a), the electrical field distribution having a sinusoidal shape of which the amplitude is ΔE_{z} is simultaneously formed in the active layer 14 by the piezoelectricity. The size of the amplitude ΔE_{z} of the electrical field distribution depends on the amplitude of the elastic wave W to be supplied, and the frequency depends on the frequency of the elastic wave W. When frequency of the elastic wave W is set to ν and the phase velocity is set to V, the period Λₙ of the refractive-index distribution according to the strain is represented by [Equation 1].

$${Λ}_{n} = \frac{V}{v} \qquad ( 1 )$$

The electrical field distribution according to the strain distribution also has the same period.

Even if the internal electrical field E_{z} is increased and decreased by ΔE_{z} with the turn-on electrical field Eₜₕ sandwiched, the gain G is similarly decreased from the maximum value G₀ and is set to G₁. As a result, the period Λₑ of the gain distribution formed by the electrical field distribution having the period Λₙ shown in Equation (1) is represented by [Equation 2].

$${Λ}_{e} = \frac{V}{2 v} \qquad ( 2 )$$

That is, as shown in FIG. 5(b), the gain distribution having the period of the half of the period Λₙ of the refractive-index distribution is formed along the traveling direction of the elastic wave W by supplying the elastic wave W in the state where the turn-on electrical field Eₜₕ is applied to the active layer 14. Since the gain distribution functions as the diffraction grating, the laser oscillation of the light L of the wavelength corresponding to the Bragg condition decided by the period Λₑ is alternatively performed in the laser element 2A.

So as to realize this gain distribution type distribution feedback and output the light L of the single wavelength, the laser device 2 has the controlling means 2C for controlling the drive power supply 2B and the elastic wave supplying means 2D or the like as shown in FIG. 2. The controlling means 2C has the turn-on voltage setting part 40 and the elastic wave adjusting part 41.

The controlling means 2C is, for example, a personal computer (PC) provided with a CPU containing a ROM and a RAM. The CPU executes a control program recorded on the ROM, and thereby each function of the turn-on voltage setting part 40 and elastic wave adjusting part 41 is realized. As described above, the controlling means 2C also has a function to analyze the detection result of the detecting part 4.

The turn-on voltage setting part 40 sets a turn-on voltage Vₜₕ as a threshold voltage corresponding to the turn-on electrical field Eₜₕ of the laser element 2A. Specifically, the turn-on voltage setting part 40 applies each voltage to the laser element 2A sequentially while controlling the drive power supply 2B to change a voltage from an initial voltage V1 (for example, 0) by a fixed value (dV). When each voltage is applied to the laser element 2A, the value of the current flowing into the laser element 2A is acquired from the drive power supply 2B, and a differentiation resistance (dV/dI) is calculated from a plurality of groups (I1, V1), (I1+dI, V1+dV) of the obtained current and voltage.

In the turn-on electrical field Eₜₕ where the gain G becomes the maximum value G₀, the current amount injected into the active layer 14 become the maximum, and the differentiation admittance due to the current becomes infinite. On the other hand, when exceeding the turn-on electrical field Eₜₕ, the leak current components rapidly increasing exist in parallel, and the differentiation admittance thereby is rapidly increased. Since the differentiation admittance of the whole laser element 2A is given by the sum of the above two kinds of differentiation admittance, the differentiation admittance of the whole laser element 2A becomes the approximate minimum in the turn-on electrical field Eₜₕ. Since the differentiation resistance is proportional to the reciprocal number of the differentiation admittance, the differentiation resistance (dV/dI) becomes the approximate maximum value in the turn-on electrical field Eₜₕ where the gain G becomes the maximum value G₀, and the voltage at this time is set as the turn-on voltage Vₜₕ.

The elastic wave adjusting part 41 is electrically connected to the spectrum detecting means 2E, high-frequency power supply 31A and impedance matching circuit 31B contained in the laser device 2, and adjusts the frequency ν and amplitude of the elastic wave W so as to obtain a desired spectrum state according to the detection result detected by the spectrum detecting means 2E.

More specifically, the elastic wave adjusting part 41 sweeps the frequency of the AC voltage outputted from the exciting power supply part 31, and determines the sweeping region of the frequency matching up to the gain width of the laser element 2A. Electric power to be supplied to the piezoelectric element 30 is determined so that spectrum width becomes the narrowest. The frequency and amplitude of the elastic wave W are adjusted by inputting the determined frequency into the sweeping area and the determined electric power to be supplied into the exciting power supply part 31 (high-frequency power supply 31A and the impedance matching circuit 31B), and exciting the piezoelectric element 30 on the excitation condition. In this case, in the exciting power supply part 31, according to the inputted frequency and the electric power to be supplied, the impedance matching circuit 31B inputs an optimal termination condition into the high-frequency power supply 31A, and the high-frequency power supply 31A applies the AC voltage corresponding to the termination condition to the piezoelectric element 30.

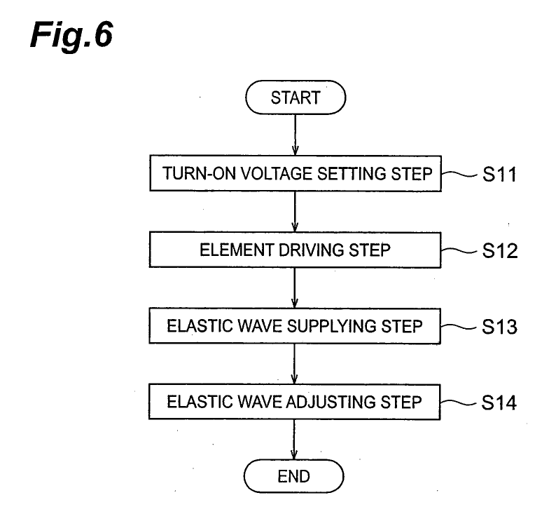

Next, the method for controlling the laser device 2 will be explained. As shown in FIG. 6, firstly, in a turn-on voltage setting step (S11), the turn-on voltage setting part 40 of the controlling means 2C sets a turn-on voltage Vₜₕ producing the turn-on electrical field Eₜₕ in the active layer 14 by the method described above. Next, the turn-on voltage setting part 40 controls the drive power supply 2B to drive the laser element 2A by the turn-on voltage Vₜₕ in an element driving step (S12). Thereby, in the active layer 14, the intersubband transition is generated, and for example, the light having a wavelength of 5 to 10 μm is generated. The generated light is repeatedly reflected in the light resonator of the laser element 2A.

Then, in an elastic wave supplying step (S13), the elastic wave adjusting part 41 controls the exciting power supply part 31 to apply the AC voltage having the predetermined frequency and the electric power to be supplied to the piezoelectric element 30. Thereby, the elastic wave W having the amplitude decided by the frequency ν corresponding to the frequency of the AC voltage and the electric power to be supplied is supplied into the active layer 14, and the refractive-index distribution along the x-axial direction is formed in the active layer 14.

Since the turn-on electrical field Eₜₕ is applied in the active layer 14, the gain distribution having the period Λₑ of the half of the period Λₙ of the refractive-index distribution is formed when the electrical field distribution is generated by piezoelectric effect. As a result, the laser oscillation of the light L of the wavelength satisfying the Bragg condition decided by the period Λₑ of the gain distribution is alternatively performed, and the light L is outputted from the front side edge face 10a as the output end face.

The light L outputted from the laser element 2A is split to two by the half mirror 2F, one light of the split lights is outputted to the exterior of the laser device 2, and is made incident in the object 3 to be analyzed (refer to FIG. 1). The other light is made incident in the spectrum detecting means 2E. The spectrum detecting means 2E inputs the detection result into the elastic wave adjusting part 41.

Next, in an elastic wave adjusting step (S14), the elastic wave adjusting part 41 controls the exciting power supply part 31 to sweep the frequency (that is, the frequency of the AC voltage applied to the piezoelectric element 30) of the elastic wave W, and determines a sweeping region of the frequency matching up to the gain width of the laser element 2A. The elastic wave adjusting part 41 determines the frequency and input power of the AC voltage applied to the piezoelectric element 30 based on the detection result of the spectrum detecting means 2E so that the spectrum state of the light L becomes a desired state in the determined sweeping region, and inputs the result into the exciting power supply part 31.

The high-frequency power supply 31A of the exciting power supply part 31 excites the piezoelectric element 30 according to the inputted frequency and inputted power. In this case, a termination condition is optimized by the impedance matching circuit 31B. As a result, the frequency and amplitude of the elastic wave W are adjusted, and the light L of the single wavelength of which the spectrum state is optimized can be outputted. It is preferable that the turn-on voltage setting part 40 calculates the differentiation resistance in the state where the elastic wave W is supplied to the laser element 2A to adjust an optimal turn-on voltage Vₜₕ finely, and resets the turn-on voltage Vₜₕ in view of the stable output of the light L of the single wavelength.

As described above, the laser device 2 can unify the wavelength of the light (for example, light having a wavelength of 5 to 10 μm) L of the wavelength of the mid-infrared to far-infrared region, and can output the light. Also, the detection result in the spectrum detecting means 2E is fed back, and spectrum width is optimized by the elastic wave adjusting part 41. Thereby, the light L suitable for the spectroscopic analysis can be obtained. Therefore, an external resonator using the diffraction grating as a resonant mirror is not required for the exterior of the laser element 2A, and a dispersive device such as the diffraction grating having wavelength selectivity is not required. As a result, the laser device 2 has a simple constitution, and the light axis is also aligned easily.

In the sweeping region determined by the elastic wave adjusting part 41, the elastic wave adjusting part 41 controls the elastic wave supplying means 2D (more specifically, exciting power supply part 31) to change the frequency of the elastic wave W continuously, and thereby the wavelength of the light L can be continuously changed. As a result, the spectroscopic analysis of the object 3 to be analyzed (refer to FIG. 1) can be performed over a wide band. Since the spectrum is optimized according to the detection result of the spectrum detecting means 2E, the analysis can be performed with high resolution and high sensitivity. That is, the spectroscopic analysis system 1 using the laser device 2 can combine the analysis with high resolution and high sensitivity, and the wide band analysis.

As described above, the period Λₑ of the gain distribution corresponds to half the period Λₙ of the refractive-index distribution. Therefore, when the light having a wavelength λ is outputted in the laser device 2, the refractive-index distribution of the twice period (that is, 2Λₑ) of the gain distribution should be formed. As a result, the frequency of the elastic wave W can be set to half as the case of using no gain distribution. For example, the frequency in the case of outputting the light having a wavelength of 9.0 μm may be about 1.3 GHz.

Since the propagation loss of the elastic wave W is proportional to the square of the frequency, the propagation loss of the elastic wave W corresponds to one-quarter when the frequency of the elastic wave W becomes half. As a result, it is possible to output the light of the single wavelength efficiently. Since the frequency of the elastic wave W becomes half, the piezoelectric element 30 is also easily excited.

When the period of the diffraction grating is generally set to Λ, the Bragg condition is represented by [Equation 3].

$$Λ = ( mb ) \frac{{λ}_{B}}{2 n} \qquad ( 3 )$$

Herein, λ_{B} means the wavelength of light producing Bragg diffraction; n means the refractive-index of a medium in which the light is propagated; and mb means a diffraction order.

When the phase velocity and frequency of the elastic wave W, and the period of the refractive-index distribution according to the strain distribution formed by the elastic wave W are, respectively, set to V, ν and Λₙ, [Equation 4] is satisfied.
V=νΛₙ (4)

Thereby, when the light having the wavelength λ is obtained by refractive-index distribution formed in the active layer 14 by the elastic wave W, [Equation 5] is satisfied from Equation (3) and Equation (4).

$$λ = \frac{( 2 n ) V}{( mb ) v} \qquad ( 5 )$$

So as to output the light having the desired wavelength λ from Equation (5) and reduce the frequency of the elastic wave W, for example, it is considered that the diffraction order is also increased. However, since the diffraction efficiency is decreased when the diffraction order of a high order is used, as a result, the single mode cannot be efficiently performed.

On the other hand, since the frequency of the elastic wave W can be made half by forming the gain distribution in the laser device 2, a primary diffraction having a high diffraction efficiency can be used. Thereby, in the gain distribution type distribution feedback, the diffraction efficiency is also increased, and the single-mode can be more efficiently performed.

When diffracting the light having the wavelength λ by using the primary diffraction in the gain distribution formed along the light axis direction (x-axial direction) of the light resonator in the active layer 14, [Equation 6] is satisfied from Equation (3).

$${Λ}_{e} = \frac{λ}{2 n} \qquad ( 6 )$$

Since the period Λₑ of the gain distribution becomes half of the period Λₙ of the refractive-index distribution, [Equation 7] is satisfied.

$${Λ}_{n} = 2 ( \frac{λ}{( 2 n )} ) \qquad ( 7 )$$

This shows that the light L can be generated by the refractive-index distribution and the light L can be outputted from the z-axial direction. That is, in the laser element 2A, the light L can also be outputted not only from the front side edge face 10a but also, for example, the both surfaces of the laser element 2A. The light outputted from other than the front side edge face 10a can be used as monitor light.

Since the laser element 2A before supplying the elastic wave W is driven in the method for controlling the laser device 2, and the turn-on voltage Vₜₕ corresponding to the turn-on electrical field Eₜₕ is calculated for every laser element 2A, the desired gain distribution can be reliably formed in the active layer 14. Since a feedback according to the spectrum state of the light L is started by repeating S11 to S14 of the controlling method at the time of the operation of the laser device 2, the spectrum state can be maintained in the optimal state.

Particularly, in the operation of the laser element 2A (for example, when performing the spectroscopic analysis), the fluctuation of the turn-on voltage Vₜₕ may be generated by thermal influence. However, the turn-on electrical field Eₜₕ can be reliably applied to the active layer 14 by performing the turn-on voltage setting step (S11) during the operation of the laser element 2A. As a result, even if the drive condition is fluctuated by thermal influence or the like during the operation of the laser element 2A, the elastic wave W is supplied into the active layer 14 in the state where the turn-on electrical field Eₜₕ is applied to the active layer 14. Thereby, since the gain distribution is reliably formed in the active layer 14, the light having the single wavelength can be stably outputted over the long run.

### Second Embodiment

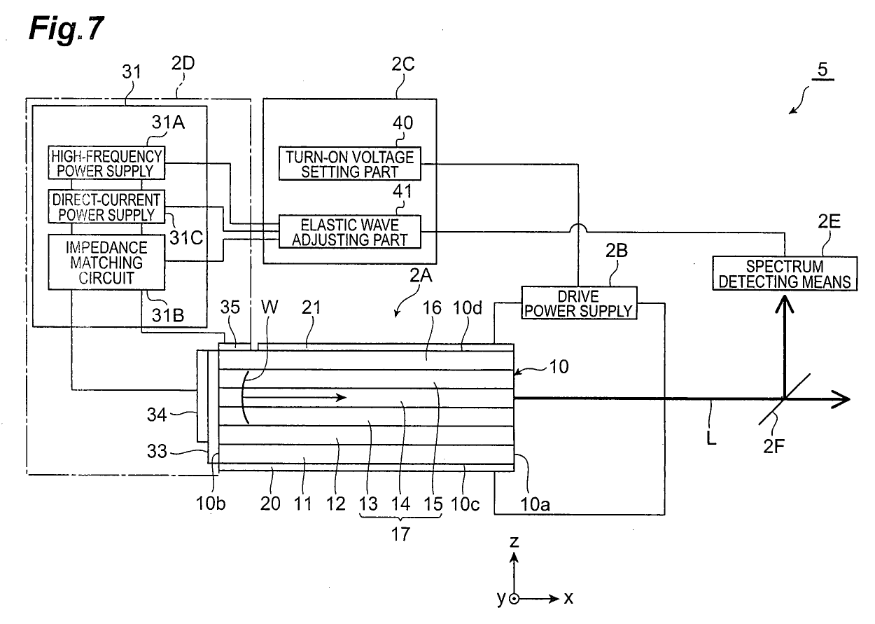

FIG. 7 is a schematic view showing the constitution of the laser device according to the second embodiment. The constitution of a laser device 5 is mainly different from that of the laser device 2 of the first embodiment in that the elastic wave supplying means 2D is composed by a semiconductor film 33, metal films 34 and 35 as a pair of electrodes and the exciting power supply part 31. The laser device 5 will be explained focusing around this regard. The same reference numerals are given to the same elements as the constituent elements of the laser device 2 of the first embodiment to preclude a necessity for overlapping explanation thereof.

The semiconductor film 33 is provided on the back side edge face 10b, and the thickness of the semiconductor film 33 is, for example, about several μm. The semiconductor film 33 has a different conductive type (that is, p-type) from a conductive type (that is, n-type) of the clad layers 12 and 16, waveguide core layers 13 and 15, active layer 14 and semiconductor substrate 11. Therefore, a p-n junction is formed by the laminated body 10 and the semiconductor film 33.

For example, the semiconductor firm 33 is formed by diffusing p-type impurities (for example, Zn) from one end face of the laminated body obtained by laminating the clad layers 12 and 16, the waveguide core layers 13 and 15 and the active layer 14 on the semiconductor substrate 11. In this case, a region other than the semiconductor film 33 out of the laminated body in which the p-type impurities are partially diffused becomes the laminated body 10. The semiconductor film 33 can also be formed by newly growing a film formed of a p-type semiconductor on the back side edge face 10b of the laminated body 10.

The metal film 34 is made of, for example, Au, and is formed on the semiconductor film 33 by the evaporation method or the sputtering method. The metal film 35 is formed of AuGe/Ni/Au. The metal film 35 is provided on the clad layer 16 of the side of the back side edge face 10b, and the metal film 35 is insulated electrically from the electrode 21. The metal films 34 and 35 as a pair of electrodes are electrically connected to the exciting power supply part 31.

The exciting power supply part 31 has further a direct-current power supply 31C for applying a reversed bias voltage to the semiconductor film 33, and the high-frequency power supply 31A, the direct-current power supply 31C and the impedance matching circuit 31B are electrically connected with each other.

In the laser device 5 having the above constitution, the p-type semiconductor film 33 is provided on the back side edge face 10b of the laminated body 10 made of an n-type semiconductor to form a p-n junction. When the AC voltage is applied to the metal films 34 and 35 by the high-frequency power supply 31A while the reversed bias voltage is applied to the pair of metal films 34 and 35 by the direct-current power supply 31C, most of the voltage applied to the metal films 34 and 35 is applied to a depletion region, and thereby a piezoelectric driving force is generated. As a result, the elastic wave W of the frequency ν corresponding to the frequency of the AC voltage is propagated into the waveguide 17 starting from the back side edge face 10b.

Thus, in the laser device 5, the elastic wave W can be supplied into the waveguide 17. Thereby, in the same manner as the method for controlling the laser device 2 of the first embodiment, the gain distribution is formed in the active layer 14. That is, in the state where the controlling means 2C controls the drive power supply 2B to apply the turn-on voltage Vₜₕ and thereby the turn-on electrical field Eₜₕ is produced in the active layer 14 of the laser element 2A, the controlling means 2C controls the elastic wave supplying means 2D and supplies the elastic wave W to the waveguide 17 to form the gain distribution in the active layer 14. Therefore, the light L of the wavelength satisfying the Bragg condition decided by the period Λₑ of the gain distribution formed in the active layer 14 can be outputted. In the method for controlling the laser device 5, the elastic wave adjusting part 41 adjusts the size of the voltage outputted by the direct-current power supply 31C according to the detection result of the spectrum detecting means 2E, and thereby the elastic wave adjusting part 41 adjusts the amplitude of the elastic wave W to optimize the spectrum state of the light L.

In this case, in the same manner as the laser device 2 of the first embodiment, the frequency of the elastic wave W required for outputting the light L of the single wavelength requires only a half as compared with the case where the gain distribution is not used. The effect in which the frequency of the elastic wave W can be reduced is the same as in the case of the first embodiment. That is, the light L of the single wavelength can be efficiently and reliably outputted. The wavelength of the light L can also be changed by changing the frequency of the elastic wave W.

### Third Embodiment

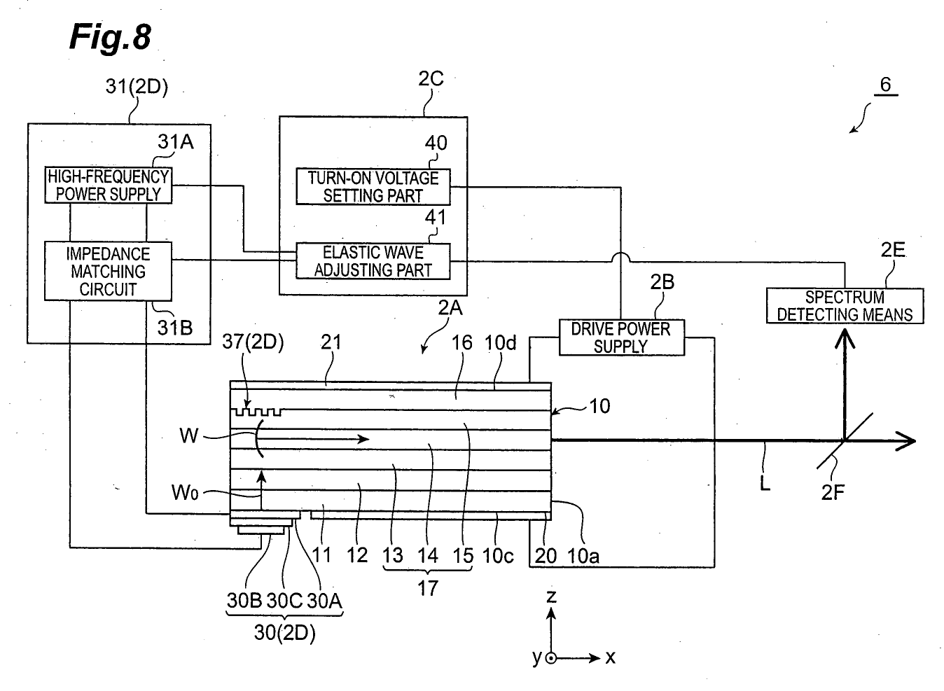

FIG. 8 is a schematic view showing the constitution of the laser device according to the third embodiment.

The constitution of a laser device 6 is different from that of the laser device 2 of the first embodiment in that the piezoelectric element 30 of the elastic wave supplying means 2D is provided on the lower surface 10c of the laminated body 10 and the elastic wave supplying means 2D has further a diffraction grating 37 built in the waveguide core layer 15 right above the piezoelectric element 30. The laser device 6 will be explained focusing around this regard. The same reference numerals are given to the same elements as the constituent elements of the laser device 2 of the first embodiment to preclude a necessity for overlapping explanation thereof.

The piezoelectric element 30 is provided on the laminated body 10 so that the metal film 30A is in contact with the lower surface 10c of the laminated body 10, and the piezoelectric element 30 is insulated electrically from the electrode 20. The diffraction grating 37 is formed by using, for example, a lithography technology after forming the waveguide core layer 15, and the period thereof, for example, is 1.5 μm.

Since the piezoelectric element 30 is expanded and contracted in the laminating direction (z-axial direction) of the laminated body 10 by applying the AC voltage to the piezoelectric element 30 in this constitution, the elastic wave W₀ is supplied in the z-axial direction. The elastic wave W₀ is converted into the elastic wave W of the waveguide mode propagated in the waveguide 17 by the diffraction grating 37 built in the upper part of the waveguide core layer 15.

In this case, the elastic wave W is propagated to the waveguide 17 consisting of the active layer 14 and the waveguide core layers 13 and 15 in the same manner as the laser device 2 of the first embodiment. Thereby, in the same manner as the method for controlling the laser device 2 of the first embodiment, the gain distribution can be formed in the active layer 14. That is, in the state where the controlling means 2C controls the drive power supply 2B to apply the turn-on voltage Vₜₕ to the laser element 2A, the controlling means 2C controls the elastic wave supplying means 2D to propagate the elastic wave W in the waveguide 17, and thereby the gain distribution can be formed in the active layer 14. Therefore, in the same manner as the case of the laser device 2 of the first embodiment, the frequency of the elastic wave W required for outputting the light L having the wavelength λ requires only a half as compared with the case where the gain distribution is not used. The effect in which the frequency of the elastic wave W can be reduced is the same as the case of the first embodiment. That is, the propagation loss of the elastic wave W is reduced in the laser element 2A, and the light L of the single wavelength can be efficiently and reliably outputted. The wavelength of the light L can also be changed by changing the frequency of the elastic wave W.

Since the light L can also be outputted from the back side edge face 10b in the laser device 6, it is possible to use the light outputted from the back side edge face 10b as the monitor light.

### Fourth Embodiment

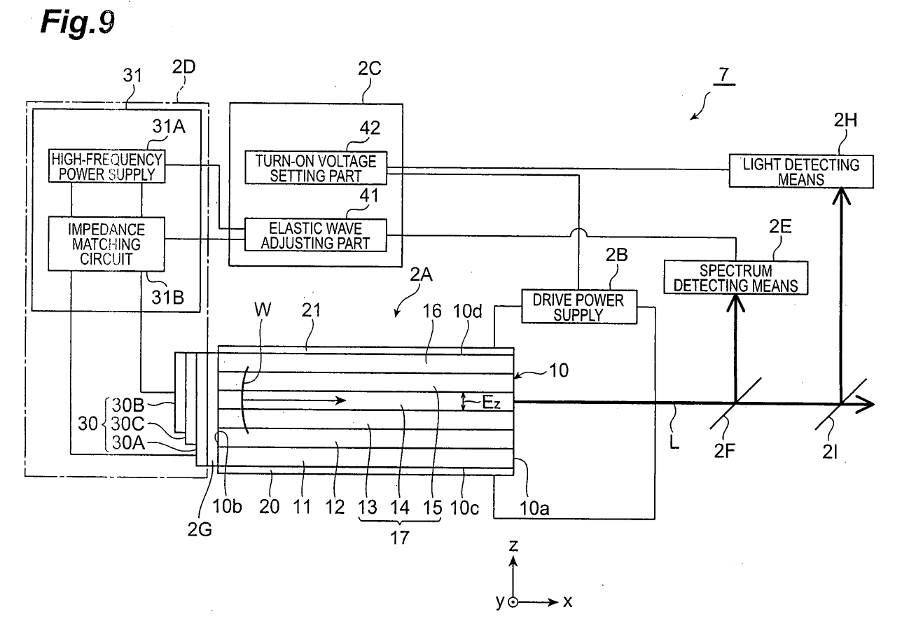

FIG. 9 is a schematic view showing the constitution of the laser device according to the fourth embodiment.

The constitution of a laser device 7 is mainly different from that of the laser device 2 of the first embodiment in that the laser device 7 has a light detecting means 2H, and a turn-on voltage setting part 42 sets the turn-on voltage Vₜₕ according to the detection result of the light detecting means 2H. The laser device 7 will be explained focusing around this regard. The same reference numerals are given to the same elements as the constituent elements of the laser device 2 of the first embodiment to preclude a necessity for overlapping explanation thereof.

The light detecting means 2H is, for example, an MCT detector, and detects the intensity of the light split by a half mirror 2I out of the light L outputted from the front side edge face 10a of the laser element 2A.

The light detecting means 2H is electrically connected to the controlling means 2C, and the turn-on voltage setting part 42 contained in the controlling means 2C sets the turn-on voltage Vₜₕ according to the detection result of the light detecting means 2H. Specifically, since the gain G becomes the maximum value G₀ when the intensity of the light L outputted from the front side edge face 10a becomes the maximum, the drive power supply 2B is controlled to increase the injecting current to the laser element 2A, and the voltage is set as the turn-on voltage Vₜₕ when the light intensity detected by the light detecting means 2H becomes the maximum value.

The method for controlling the laser device 7 is mainly different from the method for controlling the laser device 2 of the first embodiment in that the turn-on voltage Vₜₕ is set according to the detection result of the light detecting means 2H. That is, in the turn-on voltage setting step (S11) shown in FIG. 6, the turn-on voltage setting part 42 controls the drive power supply 2B to drive the laser element 2A at a predetermined voltage in the method for controlling the laser device 7. Thereby, the intensity of the outputted light L is detected by the light detecting means 2H. The turn-on voltage setting part 42 sets the voltage when the intensity of the light L detected by the light detecting means 2H become the maximum as the turn-on voltage Vₜₕ while controlling the drive power supply 2B to change the voltage (while changing the injecting current).

The method for controlling the laser device 7 after setting the turn-on voltage Vₜₕ is the same as that of the case of the first embodiment. That is, in the element driving step (S12), the turn-on voltage Vₜₕ is applied to the laser element 2A to drive the laser element 2A. In the elastic wave supplying step (S13), the elastic wave supplying means 2D supplies the elastic wave W to the laser element 2A to which the turn-on voltage Vₜₕ is applied. Thereby, the gain distribution having the period of half of the period of the strain distribution due to the elastic wave W is formed in the active layer 14, and the light L of the single wavelength is outputted.

In the elastic wave adjusting step (S14), according to the detection result of the spectrum detecting means 2E, the elastic wave adjusting part 41 controls the elastic wave supplying means 2D to adjust the frequency and amplitude of the elastic wave W so that the spectrum state of the light L becomes optimal. As a result, the light L of the single wavelength of which the spectrum state is optimized can be outputted.

The turn-on voltage setting part 42 adjusts the optimal turn-on voltage Vₜₕ finely according to the detection result of the light detecting means 2H in the state where the elastic wave W is supplied to the laser element 2A, and resets. Since the turn-on electrical field Eₜₕ is stably applied to the active layer 14 of the laser element 2A, the light L of the single wavelength can be stably outputted over the long run.

In the same manner as the laser device 2 of the first embodiment, the frequency of the elastic wave W required for outputting the light L having the wavelength λ requires only a half as compared with the case where gain distribution is not used. The effect in which the frequency of the elastic wave W can be reduced is the same as the case of the first embodiment. That is, the propagation loss of the elastic wave W in the laser element 2A is reduced, and the light L of the single wavelength can be efficiently and reliably outputted. The wavelength of the light L can also be changed by changing the frequency of the elastic wave W.

Also, in the laser device 7, during the operation of the laser device 7, the turn-on voltage setting part 42 controls the drive power supply 2B so that the detection result of the light detecting means 2H always becomes the maximum value. When the operating time of the laser element 2A becomes long, the light intensity of the laser element 2A may be changed by the influence of temperature or the like. However, the light L of the single wavelength can be stably outputted over the long run by applying feedback to the voltage applied to the laser element 2A as described above based on the detection result of the light detecting means 2H.

The controlling means 2C of the laser device 7 can have the function of the turn-on voltage setting part 40 contained in the laser device 2 of the first embodiment. In this case, for example, the turn-on voltage setting part 40 sets the turn-on voltage Vₜₕ before applying the elastic wave W to the active layer 14, and the turn-on voltage setting part 42 can readjust the turn-on voltage Vₜₕ according to the detection result of the light detecting means 2H during the operation of the laser element 2A. In this case, the detection result of the spectrum detecting means 2E is fed back, and the state of the elastic wave W is optimized by the elastic wave adjusting part 41. Also, the detection result of the light detecting means 2H is fed back and the turn-on electrical field Eₜₕ is optimized by the turn-on voltage setting part 42. Thereby, the spectrum state of the light L can be reliably optimized, and the light L suitable for the spectroscopic analysis can be obtained.

Although the light detecting means 2H is provided in the embodiment, for example, the light detector contained in the spectrum detecting means 2E can also be used as the light detecting means 2H.

Although the electrical field is symmetrically modulated to the turn-on electrical field Eₜₕ in the laser devices 2 and 5 to 7 of the first to fourth embodiments, the electrical field may not be necessarily modulated symmetrically. The voltage near the turn-on voltage Vₜₕ corresponding to the turn-on electrical field Eₜₕ can be applied to the laser element 2A, and periodic modulation may be added to the internal electrical field E_{z} in the active layer 14.

The constitution of the laser element 2A shown in the first to the fourth embodiments is not particularly limited as long as the light having the wavelength of the mid-infrared region or more can be emitted and the light can be effectively confined, and a GaInNAs layer can also be used instead of a GaAs layer. Although the quantum cascade laser element composed by GaAs/AlGaAs is used for the laser element 2A, for example, the laser element 2A is composed by a cubic III-V compound semiconductor such as InAlAs/InGaAs, InAs/GaSb and GaN and can be oscillated with the wavelength of the mid-infrared region or more. The semiconductor substrate 11, the clad layers 12 and 16, the waveguide core layers 13 and 15 and the active layer 14 only need to be composed by a semiconductor having piezoelectricity.

Furthermore, in the elastic wave supplying means 2D, a means for generating the elastic wave is not limited to a means using the piezoelectric element 30, and a means using a p-n junction composed by the laminated body 10 and a different conductive type semiconductor film 33 is available. The means for generating the elastic wave is not limited as long as the elastic wave W traveling in the x-axial direction in the active layer 14 can be supplied. For example, a surface elastic wave may be used as long as the elastic wave W can be propagated in the active layer 14.

Although the elastic wave W is propagated in the waveguide 17 in the laser element 2A, the elastic wave W only needs to be propagated in the active layer 14.

Furthermore, although the case where laser devices 2 and 5 to 7 are applied to the spectroscopic analysis system 1 is explained, the laser device according to the present invention, for example, can also be suitably used as the light source in the light communication system.

Although the controlling means 2C has the elastic wave adjusting part 41 and optimizes the spectrum state of the light L according to the detection result of the spectrum detecting means 2E, the elastic wave adjusting part 41 and the spectrum detecting means 2E may not be provided when operating the laser devices 2 and 5 to 7 on the condition previously fixed. However, it is preferable to apply feedback to the supply condition of the elastic wave W by the spectrum detecting means 2E and the elastic wave adjusting part 41 at the time of the start of the laser devices 2 and 5 to 7 or during the operation thereof so as to optimize the spectrum state of the light L outputted from the laser devices 2 and 5 to 7. Although the elastic wave adjusting part 41 adjusts the frequency and amplitude of the elastic wave W, one of the frequency and amplitude may be adjusted.

Also, in the same manner as the case of the laser device 7 of the fourth embodiment, in the laser devices 5 and 6 of the second and third embodiments, the laser devices 5 and 6 can have further the light detecting means 2H, and the controlling means 2C can have the turn-on voltage setting part 42 instead of the turn-on voltage setting part 40. That is, the voltage when the light intensity of the light L becomes the maximum according to the detection result of the light detecting means 2H can also be set as turn-on voltage Vₜₕ in the laser devices 5 and 6. In this case, that the controlling means 2C can have the function of the turn-on voltage setting part 40 is also the same as the case of the fourth embodiment. For example, that the light detector contained in the spectrum detecting means 2E can be used as the light detecting means 2H without providing the light detecting means 2H is also the same as the case of the fourth embodiment.

Furthermore, although the laser devices 2 and 5 to 7 of the first to fourth embodiments set the turn-on voltage Vₜₕ according to the differentiation resistance due to the voltage and current applied to the laser element 2A before supplying the elastic wave W, or the light intensity of the laser element 2A, the laser devices may set the turn-on voltage Vₜₕ after supplying the elastic wave W.

As described above, according to the laser device of the present invention, the light of the single wavelength in the infrared region can be efficiently outputted, and the wavelength can be changed. According to the method for controlling the laser device of the present invention, the wavelength of the light having the wavelength of the infrared region outputted from the laser device can be efficiently unified, and the wavelength can also be changed.

It is preferable that the controlling means of the laser device includes a turn-on voltage setting part for setting the turn-on voltage based on a voltage applied to the cascade laser element by the element driving means and a current flowing into the active layer when the voltage is applied.

In this constitution, the turn-on voltage can be set for every cascade laser element. As a result, the gain distribution can be reliably formed in the active layer of the cascade laser element.

Furthermore, it is preferable that the laser device further comprises light detecting means for detecting the intensity of light outputted from the cascade laser element, and the controlling means includes a turn-on voltage setting part for setting the turn-on voltage based on the detection result of the light detecting means.

The set turn-on voltage can also be set for every cascade laser element by this constitution. As a result, the gain distribution can be reliably formed in the active layer of the cascade laser element.

Also, it is preferable that the laser device further comprises spectrum detecting means for detecting the spectrum of the light outputted from the first end face of the cascade laser element, and the controlling means includes an elastic wave adjusting part for controlling at least one of the frequency and amplitude of the elastic wave supplied by the elastic wave supplying means based on the detection result of the spectrum detecting means.

In this case, the spectrum state of the light outputted from the cascade laser element can be adjusted by adjusting at least one of the frequency and amplitude of the elastic wave based on the detection result of the spectrum detecting means.

It is preferable that the laser device further comprises an insulating film provided on the active layer in the second end face, and the elastic wave supplying means includes a piezoelectric element provided on the insulating film, and expanding and contracting in the direction approximately orthogonal to the second end face. In this case, since the elastic wave is supplied to the active layer from the second end face by expanding and contracting the piezoelectric element provided on the insulating film, the propagation loss of the elastic wave can be further reduced.

Furthermore, it is preferable that a plurality of semiconductor layers have the same conductive type in the laser device. Also, it is preferable that the elastic wave supplying means includes a semiconductor film provided on the active layer in the second end face and having a different conductive type from the conductive type of the active layer and a pair of electrodes for supplying a voltage to the semiconductor film, one electrode of the pair of electrodes being provided on the semiconductor film, and the other electrode being provided on the laminated body.

Since the semiconductor film has a different conductive type from that of the semiconductor layer, the depletion region is formed at the boundary between the semiconductor film and the active layer. When the AC voltage is applied to the depletion region by the pair of electrodes, the piezoelectric driving force is generated. The elastic wave of the frequency corresponding to the frequency of the AC voltage applied to the active layer by the piezoelectric driving force progresses in the active layer. In this case, since the elastic wave can be supplied into the active layer from the second end face, the propagation loss of the elastic wave can be further reduced.

It is preferable to set the turn-on voltage based on a voltage supplied to the cascade laser element and a current when supplying the voltage in the turn-on voltage setting step in the method for controlling the laser device. In this case, since the turn-on voltage can be set for every cascade laser element, the gain distribution can be reliably formed in the active layer of the cascade laser element.

Furthermore, it is also preferable to set the turn-on voltage based on the light intensity of the light outputted from the cascade laser element in the turn-on voltage setting step in the method for controlling the laser device. Since the turn-on voltage can be set for every cascade laser element, the gain distribution can be reliably formed in the active layer of the cascade laser element.

It is preferable that the method for controlling the laser device further comprises an elastic wave adjusting step of detecting the spectrum of the light outputted from the cascade laser element, and adjusting at least one of the frequency and amplitude of the elastic wave supplied to the active layer based on the detection result. In this case, since the elastic wave is adjusted according to the spectrum of the light outputted from the cascade laser element, the light having the desired spectrum can be outputted.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A laser device comprising:
a cascade laser element including a laminated body having a plurality of semiconductor layers laminated on a semiconductor substrate and outputting light generated in an active layer from a first end face of the first and second end faces contained in the laminated body and opposing each other,
one semiconductor layer of the plurality of semiconductor layers being the active layer in which a light-emission region generating light by an intersubband transition in a quantum well structure and an injecting region injecting electron into the light-emission region are alternately laminated along the laminating direction of the plurality of semiconductor layers and which has piezoelectricity;
element driving means for supplying a voltage to the cascade laser element to drive the cascade laser element;
elastic wave supplying means for supplying an elastic wave traveling in the direction approximately orthogonal to the first end face to the active layer; and
controlling means for supplying a turn-on voltage in which the gain of the cascade laser element becomes the approximate maximum value to the cascade laser element by the element driving means, and for supplying the elastic wave to the active layer by the elastic wave supplying means.

2. The laser device according to claim 1, wherein the controlling means includes a turn-on voltage setting part for setting the turn-on voltage based on a voltage applied to the cascade laser element by the element driving means and a current flowing into the active layer when the voltage is applied.

3. The laser device according to claim 1, further comprising light detecting means for detecting the intensity of light outputted from the cascade laser element,
wherein the controlling means includes a turn-on voltage setting part for setting the turn-on voltage based on the detection result of the light detecting means.

4. The laser device according to claim 1, further comprising spectrum detecting means for detecting the spectrum of light outputted from the first end face of the cascade laser element,
wherein the controlling means includes an elastic wave adjusting part for controlling at least one of the frequency and amplitude of the elastic wave supplied by the elastic wave supplying means based on the detection result of the spectrum detecting means.

5. The laser device according to claim 1, further comprising an insulating film provided on the active layer in the second end face,
wherein the elastic wave supplying means includes a piezoelectric element provided on the insulating film, and expanding and contracting in the direction approximately orthogonal to the second end face.

6. The laser device according to claim 1, wherein the plurality of semiconductor layers have the same conductive type;
the elastic wave supplying means includes a semiconductor film provided on the active layer in the second end face and having a different conductive type from the conductive type of the active layer, and a pair of electrodes for supplying a voltage to the semiconductor film; and
one electrode of the pair of electrodes is provided on the semiconductor film and the other electrode is provided on the laminated body.

7. A method for controlling a laser device, comprising:
a turn-on voltage setting step for setting a turn-on voltage in which a gain of a cascade laser element for outputting light generated in an active layer from a first end face of the first and second end faces contained in a laminated body and opposing each other becomes the approximate maximum value, in a laser device including the laminated body having a plurality of semiconductor layers laminated on a semiconductor substrate,
one semiconductor layer of the plurality of semiconductor layers being the active layer in which a light-emission region generating light by an intersubband transition in a quantum well structure and an injecting region injecting electrons into the light-emission region are alternately laminated along the laminating direction of the plurality of semiconductor layers and which has piezoelectricity;
an element driving step for supplying the set turn-on voltage to the cascade laser element to drive the cascade laser element; and
an elastic wave supplying step for supplying an elastic wave traveling in the direction approximately orthogonal to the first end face to the active layer of the cascade laser element.

8. The method for controlling the laser device according to claim 7, wherein the turn-on voltage is set based on a voltage supplied to the cascade laser element and a current when supplying the voltage in the turn-on voltage setting step.

9. The method for controlling the laser device according to claim 7, wherein the turn-on voltage is set based on the light intensity of the light outputted from the cascade laser element in the turn-on voltage setting step.

10. The method for controlling the laser device according to claim 7, further comprising an elastic wave adjusting step for detecting the spectrum of the light outputted from the cascade laser element and adjusting at least one of the frequency and amplitude of the elastic wave supplied to the active layer based on the detection result.
